(19) United States
(12) Patent Application Publication
(10) Pub. No.: US 2010/0084003 A1
(43) Pub. Date: Apr. 8, 2010

(54) SOLAR CELL MODULE

(76) Inventor: Chien-An CHEN, Taipei (TW)

Correspondence Address: Muncy, Geissler, Olds & Lowe, PLLC, P.O. BOX 1364, FAIRFAX, VA, 22038-1364, US

(21) Appl. No.: 12/573,514

(22) Filed: Oct. 5, 2009

(30) Foreign Application Priority Data
Oct. 6, 2008 (TW) 097138424

(51) Int. Cl. H01L 31/042

(52) U.S. Cl. 136/244

(57) ABSTRACT

A solar cell module includes a circuit board and a plurality of solar cell elements. Each of the solar cell elements is partly fastened to the circuit board and is partly protrudent from the circuit board.

### CROSS REFERENCE TO RELATED APPLICATIONS

This Non-provisional application claims priority under 35 U.S.C. §119(a) on Patent Application No(s). 097138424 filed in Taiwan, Republic of China on Oct. 6, 2008, the entire contents of which are hereby incorporated by reference.

### BACKGROUND OF THE INVENTION

1. Field of Invention

The invention relates to an electronic module and, more particularly, to a solar cell module.

2. Related Art

With exhaustion of consuming energy and improvement of global environmental consciousness, how to effectively use different energy has become one important issue at present. Since solar energy is one kind of common energy in our life, the solar cell technique has become one important developing direction.

FIG. 1 is a schematic diagram showing a conventional solar cell module 1. In FIG. 1, the conventional solar cell module 1 includes a supporting element 11 and a plurality of solar cell elements 12. The supporting element 11 supports the solar cell elements 12.

To electrically connect the solar cell elements 12, in the prior art, electrodes respectively located at two different surfaces of the solar cell elements 12 may be connected via a solder 13 in a solder mode. Thus the solar cell elements 12 may be connected in series or in parallel.

However, since the electrodes of the solar cell elements 12 are located at the two different surfaces, respectively, in the prior art, the electrodes of the solar cell elements 12 located at the different surfaces are soldered by manual operation. Thus the manufacturing efficiency of the solar cell module 1 is deteriorated and the manufacturing cost increases. In addition, manual carelessness during the manual soldering operation may cause defects of the solar cell module 1, further to deteriorate reliability of the solar cell module 1.

### SUMMARY OF THE INVENTION

This invention provides a solar cell module capable of improving manufacturing efficiency, reducing cost, and improving product reliability to improve the prior art.

According to one aspect of the invention, a solar cell module includes a circuit board and a plurality of solar cell elements. Each of the solar cell elements is partly fastened to the circuit board and is partly protrudent from the circuit board.

In one embodiment of the invention, when the solar cell module has another circuit board, the solar cell element may be sandwiched between the two circuit boards.

In one embodiment of the invention, the solar cell module may further include a plurality of conductors connecting the circuit board and the solar cell elements.

In one embodiment of the invention, the solar cell module may further include a circuit, and the solar cell elements may be connected in series or in parallel via the circuit.

According to the solar cell module in the invention, a circuit board is used to be connected with the solar cell elements. Therefore, the solar cell elements can be connected in series or in parallel via the circuit disposed at the circuit board, and the solar cell elements can be directly connected with the circuit board via surface-mount technology (SMT). Thereby, the solar cell module can be manufactured via an automatic manufacturing process to improve the manufacturing efficiency and to avoid defects caused by manual operation, further to improve reliability of the solar cell module. In addition, the solar cell module in the invention can further use a conductor, two circuit boards, or a flexible circuit board and so on to allow the electrodes located at different surfaces of the solar cell elements to be capable of being connected with the circuit board.

In addition, the solar cell element of the solar cell module is partly protrudent from the circuit board. Therefore, the solar cell element is not fully disposed on the circuit board. In other words, the size of the circuit board in the invention does not need to be too large, thereby avoiding increasing cost. Thus the circuit board can be prevented from covering the solar cell elements to reduce a light-receiving area of the solar cell elements.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a conventional solar cell module;

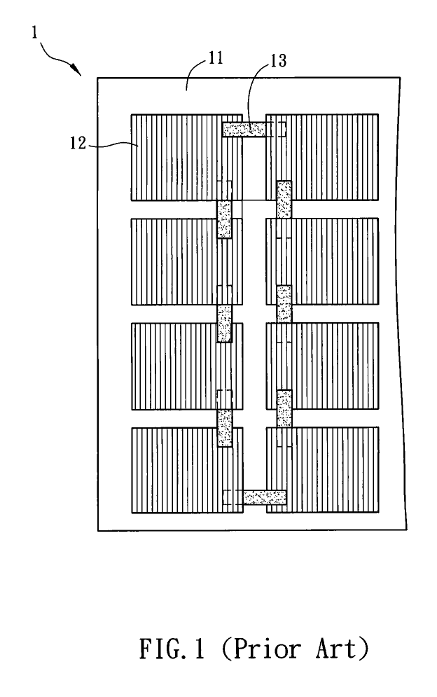

FIG. 2A is a schematic diagram showing a solar cell module according to one preferred embodiment of the invention;

FIG. 2B is a sectional schematic diagram showing the solar cell module along a line A-A in FIG. 2A; and

FIGS. 3 to 5 are schematic diagrams showing a solar cell module in different forms according to different embodiments of the invention.

### DETAILED DESCRIPTION OF THE INVENTION

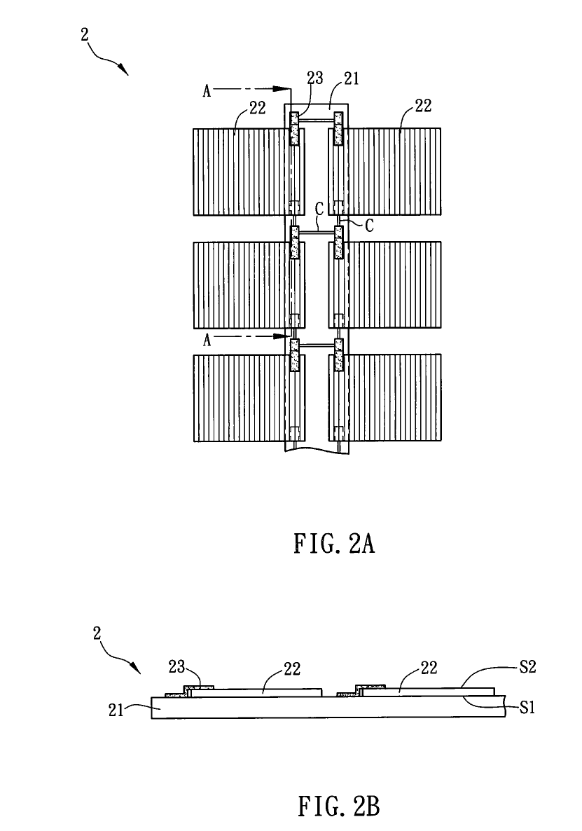

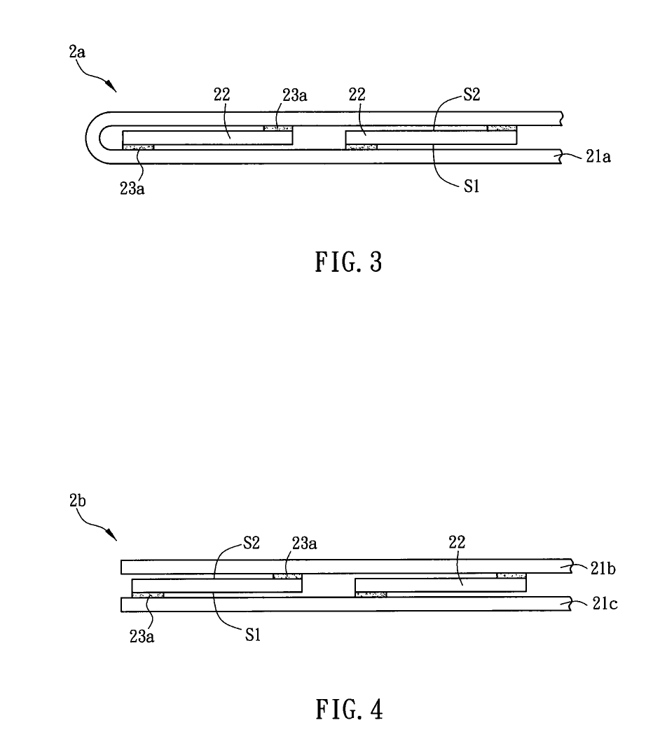

FIG. 2A is a schematic diagram showing a solar cell module 2 according to one preferred embodiment of the invention. FIG. 2B is a sectional schematic diagram showing the solar cell module 2 along a line A-A in FIG. 2A. The solar cell module 2 includes a circuit board 21 and a plurality of solar cell elements 22.

The circuit board 21 may be made of glass, sapphire, quartz, or plastic.

The solar cell element 22 may be a photovoltaic cell which may be a thin film solar cell element, a mono-crystalline silicon solar cell element, a poly-crystalline silicon solar cell element, or an organic solar cell element. The organic solar cell element may be a dye-sensitized solar cell element.

The solar cell element 22 is connected with the circuit board 21. The solar cell element 22 is partly fastened to the circuit board 21 and is partly protrudent from the circuit board 21. In other words, the solar cell element 22 is not fully disposed on the circuit board 21, and only part of the solar cell element 22 contacts the circuit board 21. In addition, in this embodiment, the solar cell element 22 has two electrodes, and the electrodes are located at two opposite surfaces S1, S2 of the solar cell element 22. However, the invention is not limited thereto. The electrodes may be located at the same surface of the solar cell element 22.

In addition, in this embodiment, the solar cell module 2 further includes a conductor 23 and a circuit C. However, the invention is not limited thereto. The conductor 23 may be a solder, a wire, or other connection elements suitable for surface-mount technology (SMT), and the conductor 23 connects the circuit board 21 and the electrode of the solar cell element 22 away from the circuit board 21 (such as the electrode at the surface S2). The circuit C is disposed at the circuit board 21, and the solar cell elements 22 are connected in series or in parallel via the circuit C.

Therefore, the solar cell elements 22 can be directly connected with the circuit board 21 via the SMT, and then the conductor 23 may connect the electrode of the solar cell element 22 located at the surface S2 and the circuit board 21 via the SMT. Thereby, the solar cell module 2 in this embodiment can be manufactured by an automatic manufacturing process to improve manufacturing efficiency and to avoid defects caused by manual operation, further to improve reliability of the solar cell module 2. In addition, the solar cell elements 22 can be connected in series or in parallel directly via the circuit disposed at the circuit board 21. In this embodiment, the left and right solar cell elements 22 are connected in parallel and the solar cell elements 22 in different rows are connected in series. However, the invention is not limited thereto. The connection mode may be different according to different designs of the circuit C. For example, all the solar cell elements 22 may be connected in series or in parallel and so on.

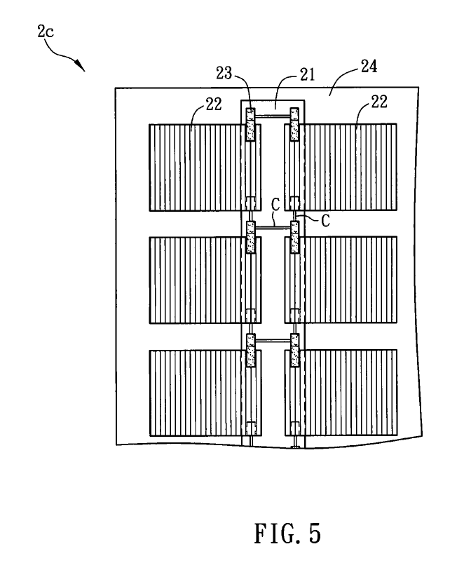

FIG. 3 is a sectional schematic diagram showing a solar cell module 2a in another form according to one embodiment of the invention. In this embodiment, a circuit board 21a of the solar cell module 2a is a flexible circuit board. Therefore, the solar cell element 22 can be disposed on the circuit board 21a first to allow an electrode at a surface S1 of the solar cell element 22 to be connected with the circuit board 21a via a conductor 23a. Then, the circuit board 21a is bent to allow the circuit board 21a to be connected with an electrode at a surface S2 of the solar cell element 22 via another conductor 23a. The conductor 23a may be a solder, a wire, or other connection elements suitable for SMT.

FIG. 4 is a sectional schematic diagram showing a solar cell module 2b in a third form according to one embodiment of the invention. In FIG. 4, the solar cell module 2b can have two circuit boards 21b, 21c. Thereby, the solar cell element 22 can be disposed on the circuit board 21c first to allow an electrode at a surface S1 of the solar cell element 22 to be connected with the circuit board 21c via a conductor 23a. Then, the circuit board 21b is disposed on the solar cell element 22 to allow the circuit board 21b to be connected with an electrode at a surface S2 of the solar cell element 22.

Therefore, via different forms of the circuit boards 21a to 21c, the manufacture of the solar cell modules 2a and 2b can be further simplified to improve the manufacturing efficiency.

FIG. 5 is a schematic diagram showing a solar cell module 2c in a fourth form according to one embodiment of the invention. In FIG. 5, the solar cell module 2c further includes a supporting element 24 for supporting a circuit board 21 and solar cell elements 22. The supporting element 24 may be a casing of an electronic device using the solar cell module 2c. Thereby, the application range of the solar cell module 2c may be further expanded.

According to the solar cell module in the embodiments of the invention, a circuit board is used to be connected with the solar cell elements. Therefore, the solar cell elements can be connected in series or in parallel via the circuit disposed at the circuit board, and the solar cell elements can be directly connected with the circuit board via the SMT. Thereby, the solar cell module can be manufactured via an automatic manufacturing process to improve the manufacturing efficiency and to avoid defects caused by manual operation, further to improve the reliability of the solar cell module. In addition, the solar cell module in the invention can further use a conductor, two circuit boards, or a flexible circuit board and so on to allow the electrodes located at different surfaces of the solar cell element to be capable of being connected with the circuit board.

In addition, the solar cell element of the solar cell module is partly protrudent from the circuit board. Therefore, the solar cell element is not fully disposed on the circuit board. In other words, the size of the circuit board in the invention does not need to be too large, thereby avoiding increasing cost. Thus the circuit board can be prevented from covering the solar cell elements to reduce a light-receiving area of the solar cell elements.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A solar cell module comprising:
a circuit board; and
a plurality of solar cell elements, each of the solar cell elements partly fastened to the circuit board and partly protrudent from the circuit board.

2. The solar cell module according to claim 1, wherein the circuit board is a flexible circuit board.

3. The solar cell module according to claim 1, wherein upper and lower surfaces of each of the solar cell elements have an electrode, respectively.

4. The solar cell module according to claim 3, further comprising:
a plurality of conductors, the electrodes being connected to the circuit board via the conductors to fasten the solar cell elements.

5. The solar cell module according to claim 1, further comprising:
another circuit board, the solar cell elements sandwiched between the two circuit boards.

6. The solar cell module according to claim 5, further comprising:
a plurality of conductors, two electrodes at upper and lower surfaces of each of the solar cell elements being connected to the two circuit boards via the respective conductors, respectively, to fasten the respective solar cell element.

7. The solar cell module according to claim 1, further comprising:
a circuit, the solar cell elements connected in series or in parallel via the circuit.

8. The solar cell module according to claim 1, wherein the solar cell elements comprise a film solar cell element, a mono-crystalline silicon solar cell element, a poly-crystalline silicon solar cell element, or an organic solar cell element.

9. The solar cell module according to claim 1, further comprising:
a supporting element for supporting the circuit board and the solar cell elements.

10. The solar cell module according to claim 1, wherein the circuit board is made of glass, sapphire, quartz, or plastic.
